(19) United States
(12) Patent Application Publication
(10) Pub. No.: US 2007/0109703 A1
(43) Pub. Date: May 17, 2007

(54) SEMICONDUCTOR INTEGRATED CIRCUIT APPARATUS, ELECTRONIC APPARATUS AND METHOD OF MANUFACTURING SEMICONDUCTOR INTEGRATED CIRCUIT APPARATUS

(75) Inventor: Hidekichi Shimura, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/548,012

(22) Filed: Oct. 10, 2006

(30) Foreign Application Priority Data
Oct. 14, 2005 (JP) 2005-300984

(51) Int. Cl. H02H 3/20

(52) U.S. Cl. 361/91.1

(57) ABSTRACT

A semiconductor integrated circuit apparatus, electronic apparatus and method of manufacturing the semiconductor integrated circuit apparatus capable of achieving low power consumption without forming a critical path. The semiconductor integrated circuit apparatus is provided with first circuit block 3 including a critical path, second circuit block 4 including no critical path and driver 5, and sets a threshold voltage of a semiconductor element of a circuit in first circuit block 3 to be equal to or lower than a threshold voltage of a semiconductor element of a circuit in second circuit block 4, sets a supply voltage to be supplied to first circuit block 3 to be equal to or higher than a supply voltage to be supplied to second circuit block 4, thereby eliminating the critical path in first circuit block 3, sets a threshold voltage of a semiconductor element of a circuit in driver 5 to be equal to or lower than the threshold voltage of the semiconductor element of the circuit in second circuit block 4, and sets a supply voltage to be supplied to driver 5 to be equal to or lower than the supply voltage to be supplied to second circuit block 4, thereby reducing power consumption of driver 5.

### BACKGROUND OF THE INVENTION

1. Field of the Invention

The present invention relates to a semiconductor integrated circuit apparatus and electronic apparatus with various functions, and a method of manufacturing the semiconductor integrated circuit apparatus, and more particularly, to a reduction of power consumption in a system LSI (Large Scale Integration).

2. Description of Related Art

As a conventional technique for designing low power-consumption LSIs, there is a technology called “dual threshold voltage/supply voltage (dual Vt/Vdd). This technology is designed as follows.

For a semiconductor element forming a critical path, a threshold voltage (Vt) is decreased and a supply voltage (Vdd) is increased. On the other hand, for a semiconductor element forming no critical path, a threshold voltage (Vt) is increased and a supply voltage (Vdd) is decreased.

The above described design technique reduces power consumption during operation of the LSI and both a sub-threshold leakage current and a sub-threshold leakage current the system LSI during standby time together. For example, claim 2 of Patent Document 1 (Japanese Patent No.3498641) describes a specific example of realizing the above described contents. Furthermore, there is also a description that applying a technology described in Non-Patent Document 1 to an actual LSI produced an effect of reducing power consumption by 60% to 65%. Non-Patent Document 1 is David Kung, et al., “Pushing ASIC Performance in a Power Envelope”, DAC 2003, Jun. 2, 2003.

When 90 nm to 65 nm is achieved in a process technology, hundreds of millions of transistors (Tr) can be integrated on a single chip of a system LSI.

For example, a voice processing function, photographic image processing function (e.g., JPEG processing) and video process function (e.g., MPEG2 processing) have been conventionally realized on separate chips, but it is becoming possible to realize these functions on a single system LSI.

FIG. 15 is a conceptual diagram showing an example of a system LSI chip with various functions on a single chip. In FIG. 15, reference numeral 900 denotes a system LSI chip with various functions on a single chip and 901 denotes an I/O circuit block. Furthermore, functional blocks are assumed as follows. Functional blocks M1, M2, M3 and M4 are memory blocks such as SRAM, ROM and DRAM. Functional blocks A1, A2, A3 and A4 (A3 and A4 are not shown) are analog blocks such as A/D, D/A and power circuit. Functional blocks L1, L2 ,L3 ,L4 ,L5 ,L6 ,L7 and L8 are logic signal processing blocks such as a voice processing function, photographic image processing function (e.g., JPEG processing) and video process function (e.g., MPEG2 processing).

FIG. 16 shows examples of the relationship between a path delay and a count with respect to a functional block. This figure shows a path delay value on the horizontal axis and a count which corresponds to a certain path delay value between flip flops on the vertical axis. FIG. 16(A) shows an example of a functional block of voice processing, FIG. 16(B) shows an example of a functional block of photographic image processing (e.g., the JPEG processing) and FIG. 16(C) shows an example of a functional block of video processing (e.g., the MPEG2 processing). Since the required processing capacity differs between the respective functions of voice processing function, photographic image processing functions (e.g., the JPEG processing) and video process function (e.g., the MPEG2 processing), when a path delay is shown on the horizontal axis and a count corresponding to a path delay value between flip flops is shown on the vertical axis, the path delay value at a peak also differs as shown in FIG. 16(A), FIG. 16(B) and FIG. 16(C). A path delay value at a peak for each functional block generally increases depending on the functional block in order of voice processing function<photographic image processing function<video process function.

When an attempt is made to operate a system LSI on a single system clock, the operating frequency at which each path of the system LSI must operate is generally determined and a necessary path delay value is determined.

In FIG. 16(A), FIG. 16(B) and FIG. 16(C), a path delay value which is necessary for operation on a certain single clock is shown with the vertical line. A path having a value equal to or greater than the path delay value necessary for operation on this single clock becomes a critical path. As is clear from FIG. 16(A), FIG. 16(B) and FIG. 16(C), the size of critical path changes for each of the plurality of functional blocks. What is missing in the above described discussions including Patent Document a and becomes an important issue when actually designing a system LSI having a variety of functional blocks is a problem of wiring delays between functional blocks. What becomes important as well as a critical path within a functional block when designing a large-scale system LSI is a critical path including wiring delays between functional blocks.

When trying to reduce power consumption during operation of the system LSI having a variety of functional blocks and reduce sub-threshold leakage current during standby time in consideration of the problem of critical paths including wiring delays between functional blocks, Patent Document 1 and Non-Patent Document 1 do not disclose how to solve these problems

### SUMMARY OF THE INVENTION

It is therefore an object of the present invention to provide a semiconductor integrated circuit apparatus, electronic apparatus and method of manufacturing the semiconductor integrated circuit apparatus capable of realizing low power consumption without forming a critical path.

Furthermore, it is another object of the present invention to provide a semiconductor integrated circuit apparatus, electronic apparatus and method of manufacturing the semiconductor integrated circuit apparatus capable of reducing power consumption of the semiconductor integrated circuit apparatus with a variety of functions through functional blocks in consideration of the problem of critical paths including wiring delays between functional blocks, too.

According to an aspect of the invention, a semiconductor integrated circuit apparatus comprising a plurality of circuit blocks including no critical path, wherein a threshold voltage of a semiconductor element of a circuit in one circuit block is set to be equal to or lower than a threshold voltage of a semiconductor element of a circuit in another circuit block and a supply voltage to be supplied to said one circuit block is set to be equal to or lower than a supply voltage to be supplied to said another circuit block, thereby setting power consumption of said one circuit block lower than said another circuit block.

According to another aspect of the invention, a semiconductor integrated circuit apparatus comprising: a first circuit block including a critical path; and

second and third circuit blocks including no said critical path, wherein: a threshold voltage of a semiconductor element of a circuit in said first circuit block is set to be equal to or lower than a threshold voltage of a semiconductor element of a circuit in said second circuit block and a supply voltage to be supplied to said first circuit block is set to be equal to or higher than a supply voltage to be supplied to said second circuit block, thereby eliminating the critical path in said first circuit block, and a threshold voltage of a semiconductor element of a circuit in said third circuit block is set to be equal to or lower than the threshold voltage of the semiconductor element of the circuit in said second circuit block, and a supply voltage to be supplied to said third circuit block is set to be equal to or lower than the supply voltage to be supplied to said second circuit block, thereby reducing power consumption of said third circuit block.

According to an aspect of the invention, a method of manufacturing a semiconductor integrated circuit apparatus provided with a plurality of circuit blocks including no critical path, the method comprising: a step of setting a threshold voltage of a semiconductor element of a circuit in one circuit block to be equal to or lower than a threshold voltage of a semiconductor element of a circuit in another circuit block; and a step of setting a supply voltage to be supplied to said one circuit block to be equal to or lower than a supply voltage to be supplied to said another circuit block.

According to a still further aspect of the invention, a method of manufacturing a semiconductor integrated circuit apparatus provided with a first circuit block including a critical path, second and third circuit blocks including no said critical path, the method comprising: a step of setting a threshold voltage of a semiconductor element of a circuit in said first circuit block to be equal to or lower than a threshold voltage of a semiconductor element of a circuit in said second circuit block; a step of setting a supply voltage to be supplied to said first circuit block to be equal to or higher than a supply voltage to be supplied to said second circuit block; a step of detecting that the critical path in said first circuit block is eliminated; a step of setting a threshold voltage of a semiconductor element of a circuit in said third circuit block to be equal to or lower than the threshold voltage of the semiconductor element of the circuit in said second circuit block; and a step of setting a supply voltage to be supplied to said third circuit block to be equal to or lower than the supply voltage to be supplied to said second circuit block.

According to a still further aspect of the invention, an electronic apparatus comprising said semiconductor integrated circuit apparatus according to claim 1.

According to a still further aspect of the invention, an electronic apparatus comprising said method of manufacturing a semiconductor integrated circuit apparatus according to claim 10.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a view illustrating a basic concept of the present invention;

FIG. 2 is a view showing an example of circuit blocks of a semiconductor integrated circuit apparatus according to Embodiment 1 of the present invention;

FIG. 3 is a view showing an example of the configuration of a large-scale integrated circuit apparatus using the semiconductor integrated circuit apparatus according to the above described embodiment;

FIG. 4 is a view showing an example of the arrangement of power lines and basic cell arrays in the semiconductor integrated circuit apparatus according to the above described embodiment;

FIG. 5 is a view showing an example of the internal configuration of the basic cell and the arrangement of a power line provided in the semiconductor integrated circuit apparatus according to the above described embodiment;

FIG. 6 is a view showing an example of a circuit diagram of the circuit block including a critical path in the configuration shown in FIG. 5;

FIG. 7 is a view showing an example of circuit blocks of a semiconductor integrated circuit apparatus according to Embodiment 2 of the present invention;

FIG. 8 is a view showing an example of circuit blocks of a semiconductor integrated circuit apparatus according to Embodiment 3 of the present invention;

FIG. 9 is a view showing an example of circuit blocks of a semiconductor integrated circuit apparatus according to Embodiment 4 of the present invention;

FIG. 10 is a view showing a connection relationship between the source electrode and the substrate electrode of the P-channel transistor in FIG. 9 and various supply voltages (VDDH, VDDL, VDDD and VM) and reference voltage (VSS) using a sectional view of a partially depleted type SOI structure;

FIG. 11 is a view showing a connection relationship between the source electrode and the substrate electrode of the N-channel transistor in FIG. 9 and various supply voltages (VDDH, VDDL, VDDD and VM) and reference voltage (VSS) using a sectional view of a partially depleted type SOI structure;

FIG. 12 is a view showing an example of circuit blocks of a semiconductor integrated circuit apparatus according to Embodiment 5 of the present invention;

FIG. 13 is a view showing an example of circuit blocks of a semiconductor integrated circuit apparatus according to Embodiment 6 of the present invention;

FIG. 14 is a view showing an example of an electronic circuit mounted with the semiconductor integrated circuit apparatus according to any one of Embodiments 1 to 6 of the present invention;

FIG. 15 is a conceptual diagram showing an example of a system LSI chip with various functions mounted on a single chip; and

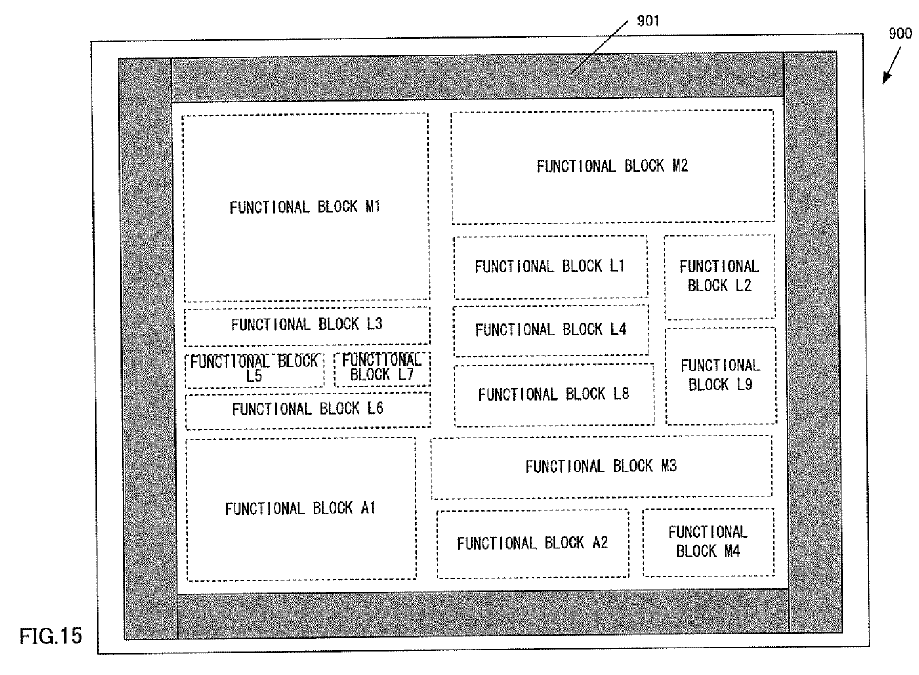

FIG. 16 is a view showing examples of a relationship between a path delay and a count with respect to a functional block.

### DESCRIPTION OF THE PREFERRED EMBODIMENT

With reference now to the attached drawings, preferred embodiments of the present invention will be explained in detail below.

(Explanation of Principle)

First, the basic principle of the present invention will be explained.

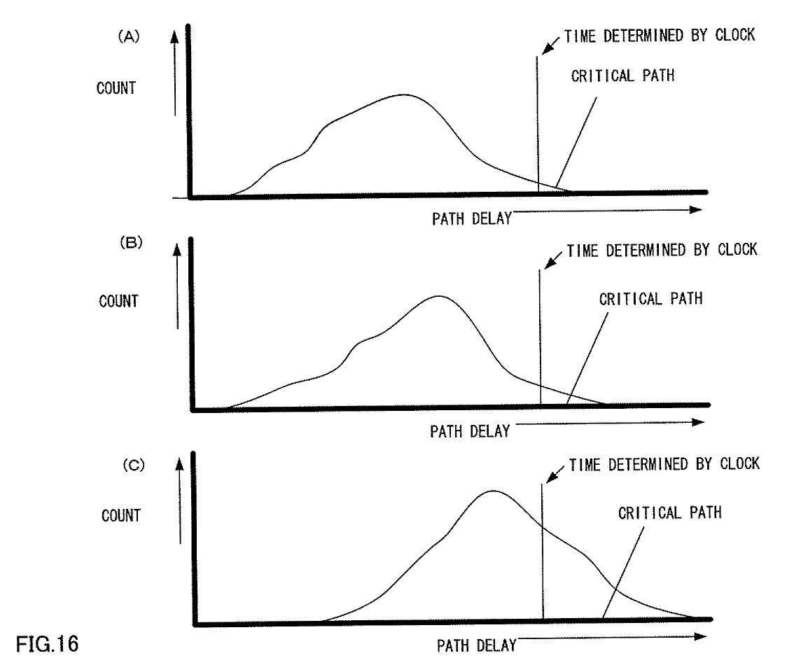

One of basic requirements for an LSI design is reductions of power consumption and sub-threshold leakage current during operation of the LSI. Therefore, a design is carried out so as to reduce power consumption by reducing a supply voltage (Vdd) supplied to a semiconductor element and reduce leakage current by increasing a threshold voltage (Vt) of the semiconductor element. For a semiconductor element forming no critical path, the design to increase the above threshold voltage (vt) and reduce the supply voltage (Vdd) is basically adopted. However, for the semiconductor element forming a critical path, a technique of increasing the operating speed of the semiconductor element is adopted by reducing the threshold voltage (Vt) of the semiconductor element or increasing the supply voltage (Vdd) or performing both to eliminate critical paths. The same applies to critical paths within a functional block and in wiring delays between functional blocks. When elimination of critical paths between functional blocks is seen from the standpoint of enhancement of the above described operation speed, critical paths are attempted to be eliminated by transforming the distribution waveform of the path delay value of the functional block shown in FIG. 16(C) into the distribution waveforms of the functional blocks as shown in FIGS. 16(A) and (B).

The present invention has a feature that, for a semiconductor element forming no critical path, a threshold voltage (Vt) of the semiconductor element is reduced and a supply voltage (Vdd) supplied to the semiconductor element is reduced. Low power consumption is achieved without changing the operation speed of the semiconductor element by reducing the threshold voltage (Vt) and reducing the supply voltage (Vdd) of the semiconductor element. That is, the speed is increased by reducing the threshold voltage (Vt) of the semiconductor element, but this results in an increase of leakage current. The supply voltage (Vdd) is reduced (though the speed decreases) so as not to increase this leakage current. Furthermore, it is also possible to reduce power consumption by reducing the supply voltage (Vdd). Therefore, only low power consumption is realized without changing the operation speed. The relationship with the operation speed need not always be an offset relationship in a strict sense and can be set appropriately using evaluation functions of the leakage current and threshold voltage (Vt) and supply voltage (Vdd) as will be described later by Expressions (1) to (14). When the distribution waveforms of the path delay values of the functional blocks shown in FIGS. 16(A), (B) and (C) are seen from the standpoint that the above operation speed is not changed, it is understandable that the distribution waveforms do not change their forms. Furthermore, when the operation speed is increased by setting the relationship between the leakage current, threshold voltage (Vt) and supply voltage (Vdd), the distribution waveform shifts to the left without changing the form.

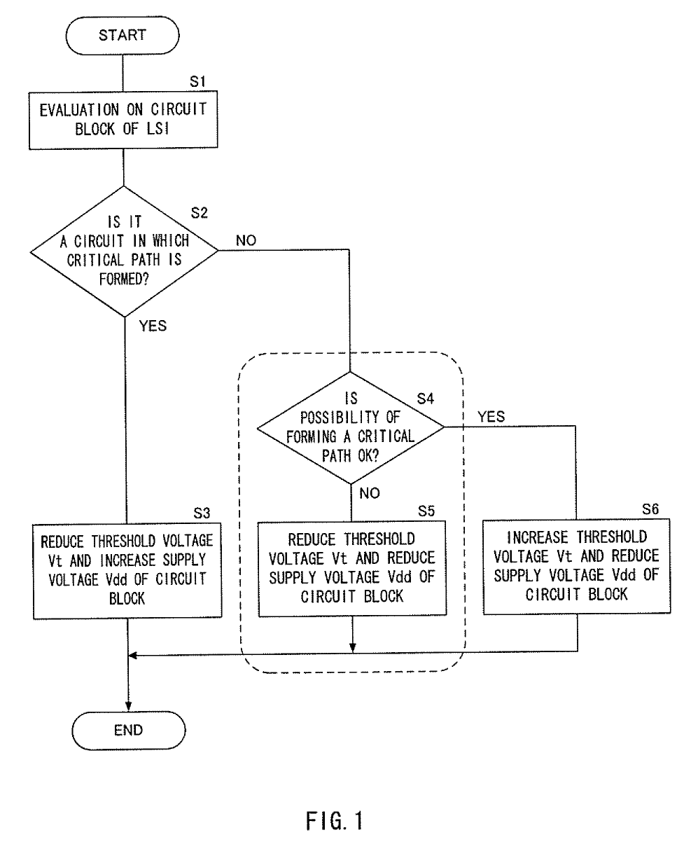

FIG. 1 is a flow chart showing a technique of setting the threshold voltage (Vt) and supply voltage (Vdd) of the semiconductor element. “S” in the figure represents each step of the flow.

First, the circuit block of the LSI is evaluated in step S1 and, in step S2, whether or not a critical path is formed in the circuit is checked. The “circuit block” of the LSI includes each circuit block in a functional block, functional block itself and critical path including wiring delays between the functional blocks.

In the case of a circuit in which a critical path is formed, a design is carried out in step S3 such that the threshold voltage (Vt) of the semiconductor element of the circuit in which the critical path is formed is decreased and the supply voltage (Vdd) is increased, and then this flow ends.

In the case of a circuit in which no critical path is formed, in step S4, whether or not a low power-consumption design having no possibility of formation of a critical path is carried out is determined. When the design with no possibility that a critical path may be formed is carried out, the threshold voltage (Vt) of the semiconductor element of the circuit is reduced in step S5 as shown with a broken line in FIG. 1 and a design for reducing the supply voltage (Vdd) is carried out, and then this flow ends. Since this is the design for reducing the threshold voltage (Vt) and reducing the supply voltage (Vdd), the operation speed of the semiconductor element does not change, and, therefore, low power consumption is achieved with no critical path being formed.

On the other hand, in step S4 when the design for further reducing power consumption is carried out even if there is a possibility of a formation of a critical path, a design for increasing the threshold voltage (Vt) of the semiconductor element of the circuit and reducing the supply voltage (Vdd) is carried out in step S6, and then this flow ends. By this means, low power consumption of the LSI is realized, but in this case, there still remains a possibility that a critical path may be newly formed. Therefore, it is necessary to conduct a test once again by changing, for example, the setting condition of a clock signal and a simulation program, and check the presence/absence of formation of a critical path. As a more preferable design method, after a circuit design is carried out in step S6, the threshold voltage (Vt) is further reduced and the supply voltage (Vdd) is reduced in step S5, thereby carrying out a design for further reducing power consumption.

### Embodiment 1

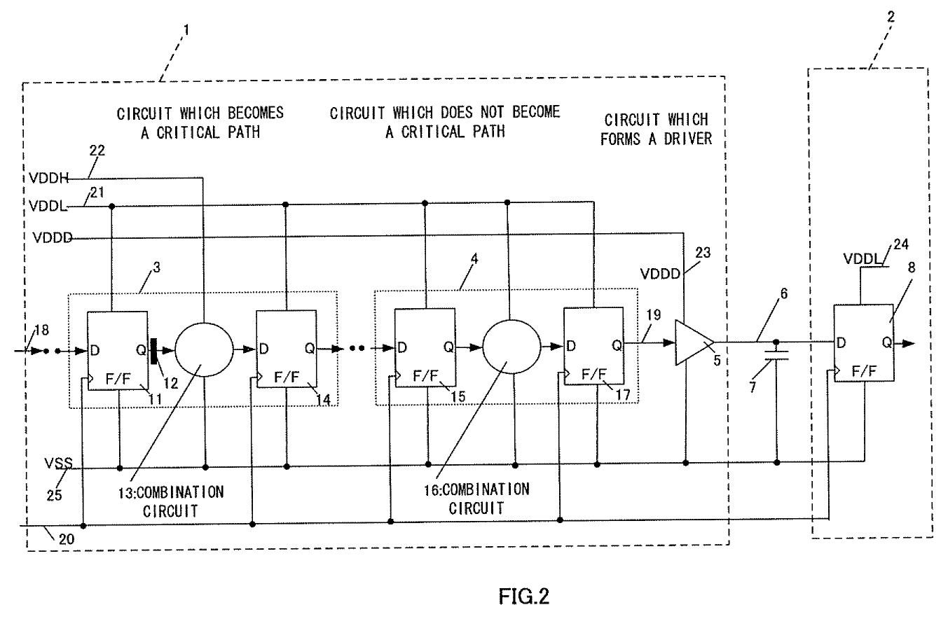

FIG. 2 shows an example of circuit blocks of a semiconductor integrated circuit apparatus according to Embodiment 1 of the present invention based on the above described basic concept. It is an example where the present invention is applied to a critical path including wiring delays between functional blocks.

In FIG. 2, reference numeral 1 denotes a first functional block and 2 denotes a second functional block, and first functional block 1 is comprised of first circuit block 3 that becomes a critical path, second circuit block 4 that does not become a critical path and driver 5 that drives a line for transmitting a signal to a circuit in second functional block 2. A signal is transmitted from first functional block 1 to the circuit in second functional block 2 through line 6, and line 6 includes capacitor 7. Furthermore, second functional block 2 is provided with flip flop a to which a signal is input from first functional block 1 through line 6.

First circuit block 3 which becomes a critical path in first functional block 1 is provided with flip flops 11 and 14, level shifter 12 and combination circuit 13, and second circuit block 4 which does not become a critical path in first functional block 1 is provided with flip flops 15 and 17 and combination circuit 16.

Input signal 18 is input to first circuit block 3 in first functional block 1 and signal 19 from second circuit block 4 is input to driver 5.

Flip flops 11, 14, 15 and 17 in first functional block 1 and flip flop 8 in second functional block 2 are operated on clock signal 20.

High potential side supply voltage 21 is supplied to flip flops 11, 14, 15 and 17 in first functional block 1 and combination circuit 16, supply voltage 22 is supplied to combination circuit 13 in the first circuit block which becomes a critical path, and supply voltage 23 is supplied to driver 5. Furthermore, supply voltage 24 is supplied to flip flop 8 in second functional block 2. Reference supply voltage 25 is supplied to first functional block 1 and second functional block 2 in common as the low potential side power supply.

Here, first circuit block 3 represents the circuit component which becomes a critical path, but strictly speaking, the critical path is from an output section of flip flop 11 to an input section of flip flop 14 passing through level shifter 12 and combination circuit 13. However, for ease of description, in this embodiment, first circuit block 3 is expressed as flip flops 11 and 14 in first circuit block 3, level shifter 12 and combination circuit 13 in first circuit block 3 for descriptive purpose.

The threshold of the circuit element forming combination circuit 13 is lower than the thresholds of flip flops 11 and 14 in first circuit block 3, flip flops 15 and 17 in second circuit block 4 and combination circuit 16. However, it goes without saying that the low threshold may also be applicable to only some circuit elements, not to “all the circuit elements forming combination circuit 13 in first circuit block 3 which becomes a critical path in first functional block 1.”

The threshold of driver 5 is configured so as to be equal to or lower than the threshold of the circuit element forming combination circuit 13 in first circuit block 3.

Hereinafter, the operations of the semiconductor integrated circuit apparatus configured as shown above will be explained.

The following explanation will describe that it is possible to lower power consumption of the semiconductor integrated circuit apparatus also in consideration of the problem of the critical path including wiring delays among the functional blocks.

Gate delays are becoming smaller with miniaturization of the semiconductor process, but wiring delays tend to increase more and more.

Delay time T_{D} of driver 5 driving line 6 for transmitting a signal from first functional block 1 to the circuit in second functional block 2 can be expressed by following Expression (1) assuming that capacitance of line 6 is C_{OUT}, the supply voltage of driver 5 driving line 6 is V_{DD}, the threshold of the P-channel transistor forming driver 5 is V_{TP}, the threshold of the N-channel transistor forming driver 5 is V_{TN}, the gain constant of the P-channel transistor forming driver 5 is β_{P} and the gain constant of the N-channel transistor forming driver 5 is β_{N.}

$$[ Expression 1 ] \\ {T}_{D} = κ {C}_{OUT} {V}_{DD} ( \frac{1}{{{β}_{P} ( {V}_{DD} - \vert {V}_{TP} \vert )}^{2}} + \frac{1}{{{β}_{N} ( {V}_{DD} - {V}_{TN} )}^{2}} ) \qquad ( 1 )$$

In order to estimate how supply voltage V_{DD} of driver 5 and threshold V_{TP} of the P-channel transistor forming driver 5 should be set, only delay time T_{DP} related to the P-channel transistor in Expression (1) will be examined here. Delay time TDP is expressed by following Expression (2).

$$[ Expression 2 ] \\ {T}_{DP} = \frac{{κ}_{P} {C}_{OUT} {V}_{DD}}{{{β}_{P} ( {V}_{DD} - \vert {V}_{TP} \vert )}^{2}} ⇒ \frac{{C}_{OUT} {V}_{DD}}{{( {V}_{DD} - \vert {V}_{TP} \vert )}^{2}} \qquad ( 2 )$$

Furthermore, in order to examine a dependency of delay time T_{DP} related to the P-channel transistor on line capacitance C_{OUT}, delay time T_{DP} related to the P-channel transistor will be more specifically calculated in the following four cases. Delay time T_{DP} is expressed by following Expressions (3) to (6) per case.

[Expression 3 ]

(Case 1)
V_{DD}=12V, V_{TP}=−0.4V T_{DP} [symbol] 1.88C_{OUT} (3)

(Case 2)
V_{DD}=1.0V, V_{TP}=−0.4V T_{DP} [symbol] 2.88C_{OUT} (4)

(Case 3)
V_{DD}=12V, V_{TP}=−0.2V T_{DP} [symbol] 1 2C_{OUT} (5)

(Case 4)
V_{DD}=1.0V, V_{TP}=−0.2V T_{DP} [symbol] 1.56C_{OUT} (6)

Therefore, it is understandable as shown in Case 3 that keeping supply voltage VDD of driver 5 at 12V and reducing an absolute value of threshold VTP of the P-channel transistor forming driver 5 to 0.2 V has an effect of reducing the wiring delay time. However, keeping supply voltage V_{DD} of driver 5 at 12V is not desirable when seeking to reduce power consumption caused by charging/discharging of capacitance C_{OUT} of the line section and achieve low power consumption.

Power consumption P caused by charging/discharging of capacitance C_{OUT} of the line section can be expressed by following Expression (7) assuming that the supply voltage of driver 5 is V_{DD} and the operating frequency is f, where K is a constant.

[Expression 4]
P=κC_{OUT}fV_{DD}² (7)

From above Expressions (2) and (7) the product of delay time T_{DP} related to the P-channel transistor and power consumption P caused by charging/discharging of capacitance C_{OUT} of the line section can be expressed by following Expression (8) assuming that the supply voltage of driver 5 is V_{DD} and the operating frequency is f.

$$[ Expression 5 ] \\ {PT}_{DP} = κ \frac{{C}_{OUT}^{2} {V}_{DD}^{3} f}{{( {V}_{DD} - \vert {V}_{TP} \vert )}^{2}} \qquad ( 8 )$$

When seeking to optimize the driver driving the line in consideration of both aspects of low power consumption and speed, not only delay time T_{DP} but also power consumption P have to be evaluated collectively. As an evaluation function at this time, PT_{DP} of Expression (8) will be evaluated.

The dependency of the value of this Expression (8) on V_{DD} and V_{TP} will be examined in the following four cases. [Expression 6]

(Case1)
V_{DD}=12V, V_{TP}=−0.4V PT_{DP} [symbol] 2.7C_{OUT}²f (9)

(Case 2)
V_{DD}=1.0V, V_{TP}=−0.4V PT_{DP} [symbol] 2.78C_{OUT}²f (10)

(Case b 3)
V_{DD}=12V, V_{TP}=−0.2V PT_{DP} [symbol] 1.72C_{OUT}²f (11)

(Case 4)
V_{DD}=1.0V, V_{TP}=−0.2V PT_{DP} [symbol] 1.56C_{OUT}²f (12)

When evaluating from PT_{DP} which is the product of delay time T_{DP} related to the P-channel and power consumption P caused by charging/discharging of capacitance C_{OUT} of the line section assuming that the supply voltage of driver 5 is V_{DD} and the operating frequency is f, it is clearly understandable that reducing supply voltage V_{DD} of driver 5 to 1.0V and reducing the absolute value of the threshold V_{TP} of the P-channel transistor forming driver 5 to 0.2V as in Case 4 is comprehensively effective.

As a method of controlling thresholds of the transistors, in this embodiment, control in a semiconductor process—that is, in general, control of an amount of channel dope—is performed.

It is clearly understandable that an effort to reduce C_{OUT}, for example, using a material having a large dielectric constant for the inter-layer insulating film also has a great effect on a reduction of P_{TDP}.

Reducing the thresholds of the P-channel transistor and N-channel transistor that form driver 5 has an effect on a reduction of power consumption of the semiconductor integrated circuit apparatus with a variety of functions in consideration of the above described problem of the critical path including wiring delays between the functional blocks, but this results in an increase of the leakage current during standby time. An increase in the leakage current during this standby time will be examined.

The leakage current of the N-channel transistor can be expressed by following Expression (13).

$$[ Expression 7 ] \\ {I}_{subtreshild} = {I}_{0} exp ( \frac{( {V}_{GS} - {V}_{TN} )}{{nV}_{T}} ) ( 1 - exp ( \frac{- {V}_{DS}}{{V}_{T}} ) ) \\ where {V}_{T} = kT / q \qquad ( 13 )$$

The leakage current will be examined assuming a case where the P-channel transistor and N-channel transistor that form driver 5 are ON and OFF, respectively.

Since the N-channel transistor is OFF, the followings are found.

V_{GS=}0Volt

V_{DS=V}_{DD}

By this means, the leakage current of the N-channel transistor can be expressed by following Expression (14).

$$[ Expression 8 ] \\ {I}_{subtreshild} = {I}_{0} exp ( \frac{( - {V}_{TN} )}{{nV}_{T}} ) ( 1 - exp ( \frac{- {V}_{DD}}{{V}_{T}} ) ) \qquad ( 14 )$$

It is understandable from this Expression (14) that the leakage current increases due to (1) a reduction of the threshold of the N-channel transistor or (2) an increase of the supply voltage.

From this standpoint, the supply voltage V_{DD} of driver 5 is preferably low, but reducing threshold V_{TH} of the N-channel transistor involves a problem of increasing the leakage current of the N-channel transistor during standby time.

In the semiconductor element forming no critical path, low power consumption may be achieved by reducing the threshold voltage (Vt) and reducing the supply voltage (Vdd) of the semiconductor element without changing the operation speed of the semiconductor element. However, reducing the supply voltage (Vdd) with respect to the leakage current during standby time causes a decrease of the leakage current, and reducing the threshold voltage (Vt) increases the leakage current. However, an increase of the leakage current during standby time caused by reducing the threshold voltage (Vt) of the semiconductor element can be handled using a circuit-related method as described in Embodiment 6.

Next, an example will be explained where the present invention is specifically applied to the semiconductor integrated circuit apparatus.

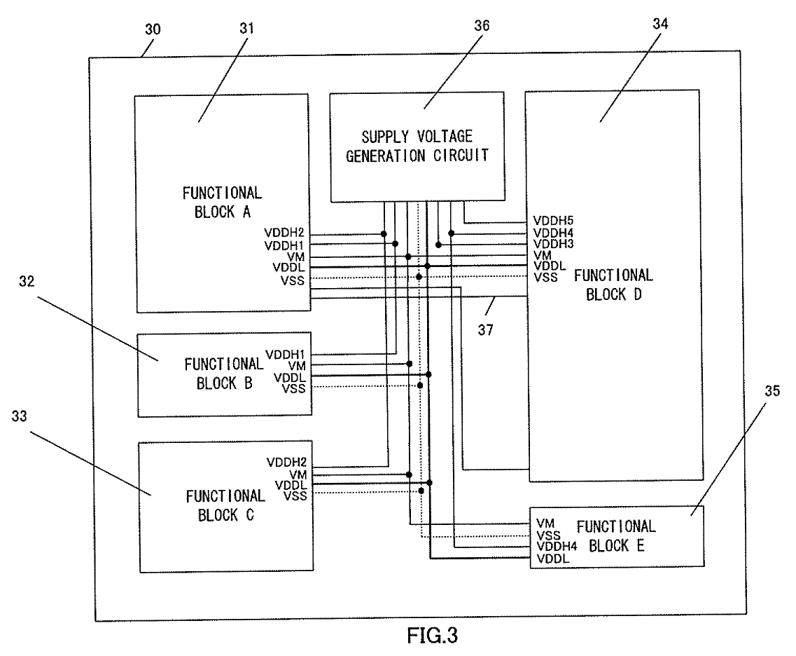

FIG. 3 shows an example of the configuration of a large-scale integrated circuit apparatus using the semiconductor integrated circuit apparatus according to this embodiment. The large-scale integrated circuit apparatus will be explained assuming a system LSI as an example. For ease of description, the semiconductor integrated circuit apparatus according to this embodiment will be explained using a block diagram of such an apparatus provided with logic signal processing functional blocks such as a voice processing function, photographic image processing function (e.g., JPEG processing), video processing function (e.g., MPEG2 processing) as the functional blocks. However, it goes without saying that substantially the same concept is applicable to a case where the memory functional block and analog functional block are mounted inside the semiconductor integrated circuit apparatus chip.

System LSI 30 shown in FIG. 3 is comprised of a plurality of functional blocks (functional block A31, functional block B32, functional block C33, functional block D34, and functional block E35) and supply voltage generation circuit 36. Supply voltage generation circuit 36 has a plurality of power supplies having a plurality of supply voltage values and supplies power to a plurality of functional blocks. The plurality of power supplies have the supply voltage values suitable for the respective processing capacities of the plurality of functional blocks and supplied to the suitable functional blocks respectively. Each of the plurality of functional blocks has one or a plurality of circuit blocks.

Supply voltage generation circuit 36 is presupposed to be supplied with one or more supply voltage values (not shown in FIG. 3) from outside system LSI 30. Power supplies having a plurality of supply voltage values necessary for system LSI 30 are generated based on these one or more supplied supply voltage values (not shown). In FIG. 3, supply voltage generation circuit 36 is provided with a reference power supply (also referred to as “VSS” or “ground VSSL”), substrate power supply VM, first power supply (VDDL) having a higher voltage than the reference power supply and a second power supply having a higher voltage than the first power supply. This embodiment will be explained with reference to a case where the second power supply has five supply voltage values (VDDHn, n=1 to 5) and the number of supply voltage values of VDDH is n=5.

Supply voltage generation circuit 36 supplies power to the respective functional blocks as follows.

(1) Functional block A31 is supplied with power supply VDDL, power supply VDDH1, power supply VDDH2 and substrate power supply VM and reference power supply VSS. The supply voltage values of power supply VDDH1 and power supply VDDH2 are set to be higher than the supply voltage value of power supply VDDL.

(2) Functional block B32 is supplied with power supply VDDL, power supply VDDH1, substrate power supply VM and reference power supply VSS. The supply voltage value of power supply VDDH1 is set to be higher than the supply voltage value of power supply VDDL.

(3) Functional block C33 is supplied with power supply VDDL, power supply VDDH2, substrate power supply VM and reference power supply VSS. The supply voltage value of power supply VDDH2 is set to be higher than the supply voltage value of power supply VDDL.

(4) Functional block D34 is supplied with power supply VDDL, power supply VDDH3, power supply VDDH4, power supply VDDHS, substrate power supply VM and reference power supply VSS. The supply voltage values of power supply VDDH3, power supply VDDH4 and power supply VDDH5 are set to be higher than the supply voltage value of power supply VDDL.

(5) Functional block E35 is supplied with power supply VDDL, power supply VDDH4, substrate power supply VM and reference power supply VSS. The supply voltage value of power supply VDDH4 is set to be higher than the supply voltage value of power supply VDDL.

Furthermore, line 37 is a line output from functional block A31 and input to functional block D34 across blocks. The above example illustrates only a line between the blocks, but there is clearly a substantial number of lines between blocks in addition to this.

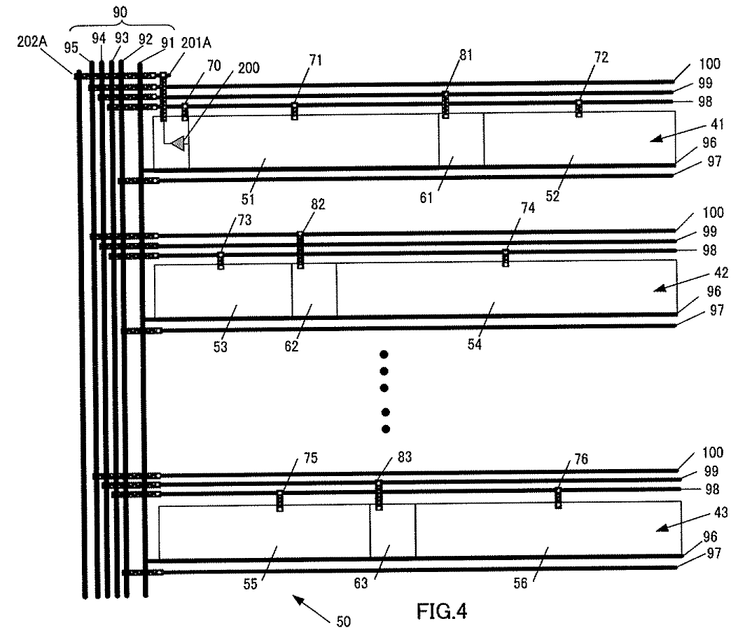

FIG. 4 shows an example of an arrangement of a power line and basic cell arrays in the semiconductor integrated circuit apparatus according to the embodiment of the present invention. FIG. 4 shows part of the semiconductor integrated circuit apparatus. A plurality of power lines 96 to 100 branched from main power line 90 are arranged parallel to the basic cell arrays and each of the plurality of power lines 96 to 100 is connected to a circuit block including a critical path and a circuit block including no critical path out of the plurality of circuit blocks included in the basic cell array. The “critical path” refers to a path in which when a clock frequency for operating the system LSI is defined, processing is not completed within an allowable time determined from the clock frequency.

In FIG. 4, main power line 90 is comprised of reference main power line 91, substrate power line 92, first main power line 93, second main power line 94 and third main power line 95. Reference main power line 91 supplies reference power supplies (VSS and ground VSS) of reference supply voltage values to the circuit block. Substrate power line 92 supplies substrate power supply (VM) to the circuit block. First main power line 93 supplies a first power supply (VDDL) which is a higher voltage (first supply voltage value) than the reference power supply, to the circuit block. Second main power line 94 supplies a second power supply (VDDHl) which is a higher voltage (second supply voltage value) than the above described first main power line, to the circuit block. Third main power line 95 supplies a third power supply (VDDH2) which is a higher voltage (third supply voltage value) than the above described second main power line, to the circuit block. VDDH can be set to two or more supply voltage values, but, in FIG. 4, the case with two values is adopted as an example.

From reference main power line 91, substrate power line 92, first main power line 93, second main power line 94 and third main power line 95 forming main power line 90, extend to reference power line 96, substrate power line 97, first power line 98, second power line 99 and third power line 100 branching from main power line 90, respectively, in the second direction (horizontal direction) in the above described line arrangement area. Substrate power line 97, first power line 98, second power line 99 and third power line 100 are connected to substrate power line 92, first main power line 93, second main power line 94 and third main power line 95, respectively.

The basic cell array is formed with a plurality of arrays of basic cells arranged in the first direction (vertical direction) with respect to main power line 90, and FIG. 4 shows an example where the basic cell array is formed with basic cells 41, 42 and 43. Basic cells 41 to 43 are each provided with a plurality of circuit blocks and have first circuit blocks 51 to 56 including no critical path and second circuit blocks 61 to 63 including a critical path. Between the basic cell arrays neighboring in the first direction, a line arrangement area (not shown) is formed. It is, for example, an area between basic cell 41 and basic cell 42 and parallel to basic cells 41 and 42.

First circuit blocks 51 to 56 each include a first semiconductor element which does not become a critical path or a first logic circuit (for example, so-called logic circuit such as AND circuit and NAND circuit). On the other hand, second circuit blocks 61 to 63 each include a second semiconductor element or a second logic circuit which becomes a critical path. Furthermore, second circuit blocks 61 to 63 may be further provided with the above described first semiconductor element or the above described first logic circuit. The threshold voltage value of the second semiconductor element or the second logic circuit is lower than the threshold voltage value of the first semiconductor element or the first logic circuit.

Furthermore, line sections 71 to 76 are lines which supply power from first power line 98 to first circuit blocks 51 to 56 of basic cells 41 to 43. Line sections 81 to 83 are lines which supply power from second power line 99 or third power line 100 to second circuit blocks 61 to 63 of basic cells 41 to 43.

For example, in a case of basic cell 41, first circuit blocks 51 and 52 including no critical path are connected to first power line 98 by line sections 71 and 72, and second circuit block 61 including a critical path is connected to second power line 99 by line section 81. Furthermore, reference power line 96 is connected to all circuit blocks. The same applies to other basic cells 42 and 43. In this way, first circuit blocks 51 and 52 are supplied with a first power supply (e.g., VDDL) from first power line 98 and second circuit block 61 is supplied with a second power supply (e.g., VDDH1) from second power line 99.

In FIG. 4, reference main power line 91 and first main power line 93 are P-channel first substrate power lines 91 and 93, respectively. P-channel first substrate power lines 91 and 93 supply a first substrate power supply (here, the above described first power supply) to the P-channel transistors of second circuit blocks 61 and 63 including the above described critical path, and P-channel first substrate power line 92 supplies a second substrate power supply (here, the above described second power supply) to the P-channel transistor of second circuit block 62 including the above described critical path.

Likewise, third main power line 95, reference power line 96 and reference power line 97 are respectively N-channel first substrate power lines 95, 96 and 97, and N-channel first substrate power lines 95, 96 and 97 supply the first substrate power supply (here, above described substrate power line 97) to the N-channel transistors of the second circuit blocks 61, 62 and 63 including the above described critical path.

At the left end of basic cell 41, driver 200 driving the line output from functional block A31 and input to functional block D34 across the blocks is provided, and a power supply of driver 200 is connected to the first power supply (e.g., VDDL) by first power line 98 through line section 70. An output from driver 200 is wired to functional block D34 via line section 201A and line section 202A.

Furthermore, the threshold voltage value of the semiconductor element of driver 200 is set to be equal to or lower than the threshold voltage value of the semiconductor element of second circuit block 61.

In the above example, although the case has been explained where the power supply of driver 200 is connected to the first power supply (e.g., VDDL) by first power line 98 through line section 70, the power supply of driver 200 may be lower than the first power supply (e.g., VDDL) when a power supply lower than the first power supply (e.g., VDDL) can be set.

Next, an example of the configuration of the basic cell and connections to the power lines and the substrate line will be explained.

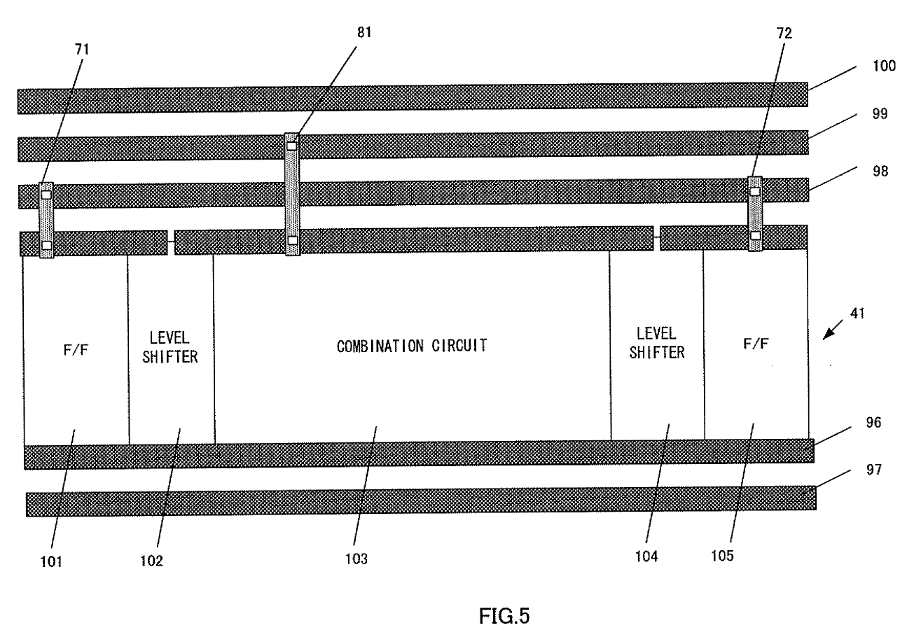

FIG. 5 is a view showing an example of the internal configuration of the basic cell and the arrangement of the power lines of the semiconductor integrated circuit apparatus according to this embodiment. Components that are same as FIG. 4 are assigned the same reference numerals and explanations of overlapping parts will be omitted.

FIG. 5 shows how combination circuit 103 including a critical path is connected to second power line 99.

Basic cell 41 is provided with flip flops (F/F) 101 and 105, level shifters 102 and 104, and combination circuit 103. Level shifters 102 and 104 interface between signal levels having different power supplies. These components form the circuit which becomes a critical path. Line section 71 is a line connecting first power line 98, the power supply of flip flop 101 and part of the power supply of level shifter 102, Line area 72 is a line connecting first power line 98, the power supply of flip flop 105 and part of the power supply of level shifter 104. Furthermore, line section 81 is a line to connect second power line 99 and part of the power supplies of level shifters 102 and 104 and the power supply of combination circuit 103.

P-channel first substrate power line 91 supplies the first substrate power supply (here, first power line 98) as the substrate power supply of the P-channel transistor of combination circuit 103.

Furthermore, N-channel first substrate power line 95 supplies the first substrate power (here, substrate power line 97) as the substrate power supply of the N-channel transistor of combination circuit 103. The same applies to basic cell 42.

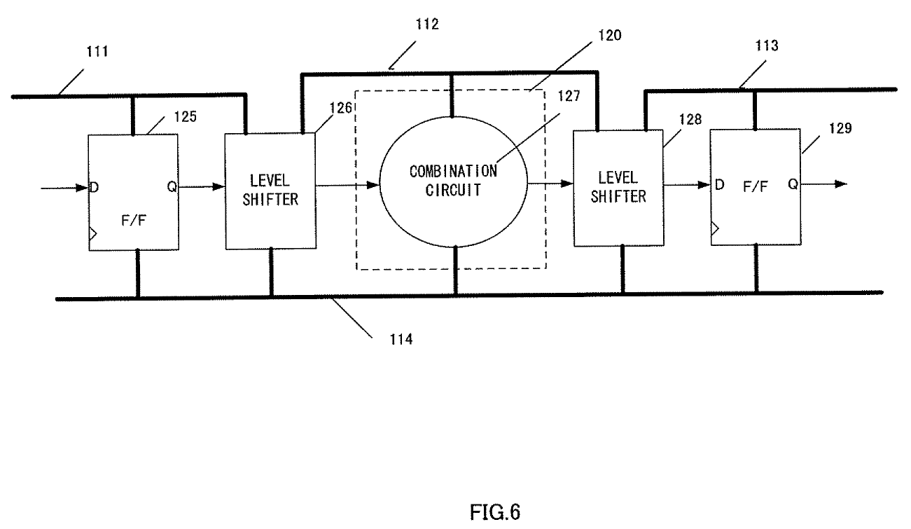

FIG. 6 is a circuit diagram showing an example of the circuit block including a critical path in the configuration shown in FIG. 5. Here, signal flows are indicated by arrows (→) FIG. 6 is corresponding to the configuration shown in FIG. 5 and is comprised of first power lines 111 and 113, second power line 112, reference power line 114, flip flops 125 and 129, level shifters 126 and 128 and combination circuit 127. Area 120 enclosed by a broken line shows an area where the threshold voltage of the semiconductor element is lower than the threshold voltage of the semiconductor element forming the circuit block forming no critical path.

By adopting the circuit configuration shown in FIG. 2 to FIG. 6, a design is carried out so as to reduce the threshold voltage (Vt) and increase in the semiconductor element which becomes a critical path, increase the threshold voltage (Vt) and reduce the supply voltage (Vdd) in the semiconductor element which does not become a critical path. In this way, the technological concept of dual Vt/Vdd is realized.

In this way, the first circuit block forming no critical path is connected to the first power line, and the first power supply (VDDL) is supplied thereto. On the other hand, the second circuit block forming a critical path is connected to the second power line, and the second power supply (VDDH or VDDHn) is supplied thereto. As a second power supply, one or more power supplies VDDHn (“n” takes one of values 1 to 5 in this embodiment) having supply voltage values suitable for processing capacities of a plurality of circuit blocks (functional blocks) from a plurality of power supplies generated in the supply voltage generation circuit are supplied. Moreover, the supply voltage value has a feature of having a supply voltage value higher than the supply voltage value of the same power supply supplied to the circuit block forming no critical path. Therefore, the semiconductor integrated circuit apparatus according to this embodiment supplies power supplies VDDHn having the supply voltage value suitable for the processing capacities of the plurality of circuit blocks including a critical path, so that it is possible to reduce power consumption.

Here, although explanations in a case where a plurality of power supplies are supplied from outside will be omitted, the basic contents are the same as the case where power is generated by the supply voltage generation circuit.

Moreover, the semiconductor integrated circuit apparatus according to this embodiment is provided with. first circuit block 3 including a critical path; second circuit block 4 including no critical path; and driver 5, wherein the threshold voltage of the semiconductor element of the circuit in first circuit block 3 is set to be equal to or lower than the threshold voltage of the semiconductor element of the circuit in second circuit block 4, and the supply voltage to be supplied to first circuit block 3 is set to be equal to or greater than the supply voltage to be supplied to second circuit block 4, thereby eliminating the critical path in first circuit block 3; and the threshold voltage of the semiconductor element of the circuit in driver 5 is set to be equal to or lower than the threshold voltage of the semiconductor element of the circuit in second circuit block 4, and the supply voltage to be supplied to driver 5 is set to be equal to or lower than the supply voltage to be supplied to second circuit block 4, thereby reducing power consumption of driver. That is, in the semiconductor element of the circuit block forming no critical path (for example, the semiconductor element of the circuit forming driver 5), power consumption is reduced without changing the operation speed of the semiconductor element by reducing the threshold voltage (Vt) of the semiconductor element and reducing the supply voltage (Vdd). In this case, reduction of power consumption can also be achieved by reducing the supply voltage (Vdd). The operation speed is therefore not changed, so that it is possible to reduce power consumption without forming a critical path. Especially, for example, in a final process of design where a critical path has been eliminated, it is possible to prevent new critical paths from being formed in the circuit block including no critical path and further reduce power consumption.

### Embodiment 2

This embodiment will be explained with reference to a mechanism which places first functional block 1 in a standby state and second functional block 2 in an operation state.

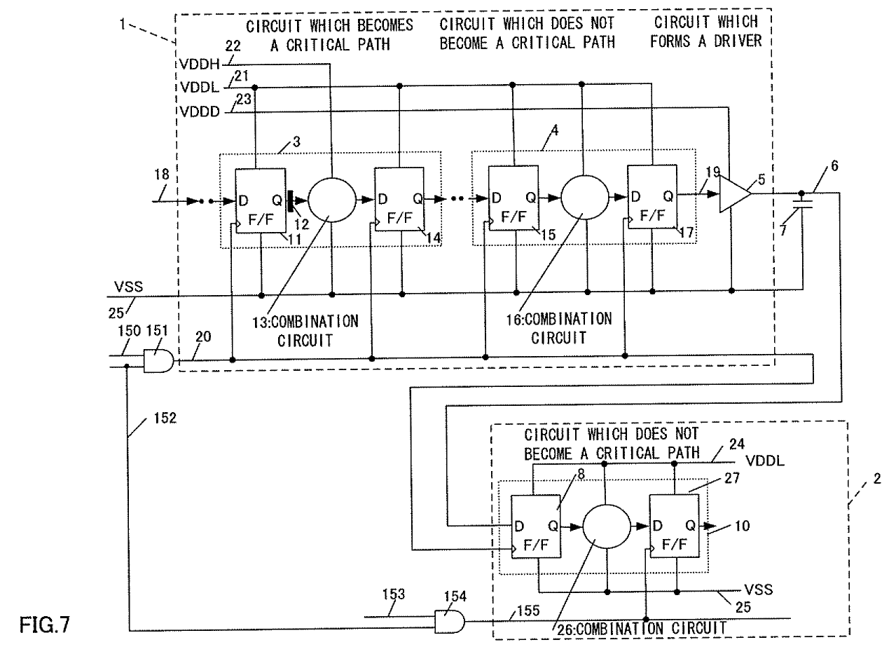

FIG. 7 is a view showing an example of circuit blocks of a semiconductor integrated circuit apparatus according to Embodiment 2 of the present invention. Components that are same as FIG. 2 are assigned the same reference numerals and explanations of overlapping parts will be omitted.

In FIG. 7, circuit block 10 which does not become a critical path in second functional block 2 is provided with flip flops 8 and 27 and combination circuit 26.

Furthermore, reference numerals 151 and 154 denote AND circuits, signal 150 setting first functional block 1 to an operation state and system clock 152 of this semiconductor integrated circuit apparatus are input to AND circuit 151 and an output from AND circuit 151 becomes clock signal 20.

Signal 153 setting second functional block 2 to an operation state and system clock 152 of this semiconductor integrated circuit apparatus are input to AND circuit 154 and output signal 155 is output from AND circuit 154.

As a method of placing first functional block 1 in a standby state, a gated clock technique is generally practiced where signal 150 setting first functional block 1 to an operation state is set to a “0” level so as to prevent system clock 152 of this semiconductor integrated circuit apparatus from being supplied to first functional block 1. However, this alone cannot completely reduce power consumption in first functional block 1 to zero, as a method for further, “power-off” may also be performed where voltages 21, 22 and 23 of power supplies supplied to first functional block 1 are set to reference supply voltage 25. In this case, an output signal from driver 5 that drives the line for transmitting a signal to the circuit in second functional block 2 from first functional block 1 becomes indeterminate. Since second functional block 2 is in an operation state, the indeterminate output signal of driver 5 is sampled by flip flop 8 in second functional block 2 to which the signal from line 6 is input. To avoid this, signal 152 having the same clock as the flip flop of first functional block 1 is used for the clock input of flip flop 8 in second functional block 2 to which the signal of above described line 6 is input. However, output signal 155 from AND circuit 154 is used for the flip flop in second functional block 2 other than flip flop 8 in second functional block 2 to which the signal of above described line 6 is input.

In this way, by using the signal having the same clock that is input to the flip flop of first functional block 1 for the clock input of flip flop 8 in second functional block 2 to which the signal of above described line 6 is input, when first functional block 1 is placed in a standby state, flip flop 8 in second functional block 2 to which the signal of above described line 6 is input is also placed in a standby state, and therefore the indeterminate output signal of driver 5 is not sampled.

### Embodiment 3

This embodiment will be explained with reference to a mechanism for further improving a sub-threshold leakage current.

In general, because V_{DD}>>V_{T} and the following expression 9 is satisfied, the leakage current increases when the threshold of the N-channel element decreases.

$$[ Expression 9 ] \\ {I}_{subtreshild} = {I}_{0} exp ( \frac{( - {V}_{TN} )}{{nV}_{T}} ) \qquad ( 15 )$$

This embodiment will reduce a sub-threshold leakage current.

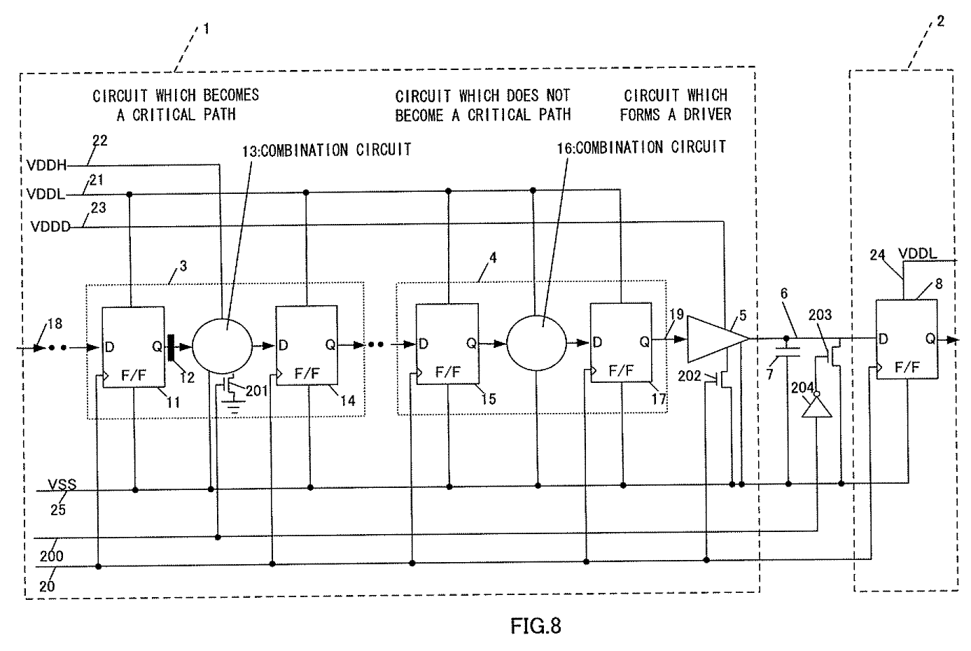

FIG. 8 is a view showing an example of circuit blocks of a semiconductor integrated circuit apparatus according to Embodiment 3 of the present invention. Components that are same as FIG. 2 are assigned the same reference numerals and explanations of overlapping parts will be omitted.

In FIG. 8, the semiconductor integrated circuit in FIG. 2 is further provided with: N-channel transistor 201 inserted between combination circuit 13 in first circuit block 3 and reference supply voltage 25; N-channel transistor 202 inserted between driver 5 and reference supply voltage 25; N-channel transistor 203 inserted between line 6 transmitting a signal to the circuit in second functional block 2 and reference supply voltage 25; and inverter 204 outputting signal 200 obtained by inverting the signal which places functional block 1 in a standby state to a gate of N-channel transistor 203.

The thresholds of above described N-channel transistor 201, N-channel transistor 202, N-channel transistor 203 and inverter 204 are the same as the thresholds of flip flops 11 and 14 in first circuit block 3, flip flops 15 and 17 in second circuit block 4 and combination circuit 16 in second circuit block 4.

Hereinafter, the operations of the semiconductor integrated circuit apparatus configured as above will be explained.

When first functional block 1 is in a standby state, above described signal 200 becomes a “0” level, and N-channel transistor 201 and N-channel transistor 202 are in an OFF state, the current path to the ground is cut off even if the threshold voltages of combination circuit 13 in first circuit block 3 and driver 5 are low. Furthermore, the thresholds of N-channel transistor 201 and N-channel transistor 202 are normal values, and a sub-threshold leakage current comparable to the transistor having lowered threshold does not flow. Therefore, the sub-threshold leakage current can be further improved.

However, when first functional block is in a standby state, above described signal 200 becomes a “0” level. As a result, the output signal of driver 5 becomes indeterminate, and it is necessary to prevent this indeterminate signal from propagating to flip flop 8 in second functional block 2 to which the signal of line 6 is input via line 6. For this reason, when first functional block 1 is in a standby state, N-channel transistor 203 is ON and a potential of line 6 is fixed to reference supply voltage 25.

### Embodiment 4

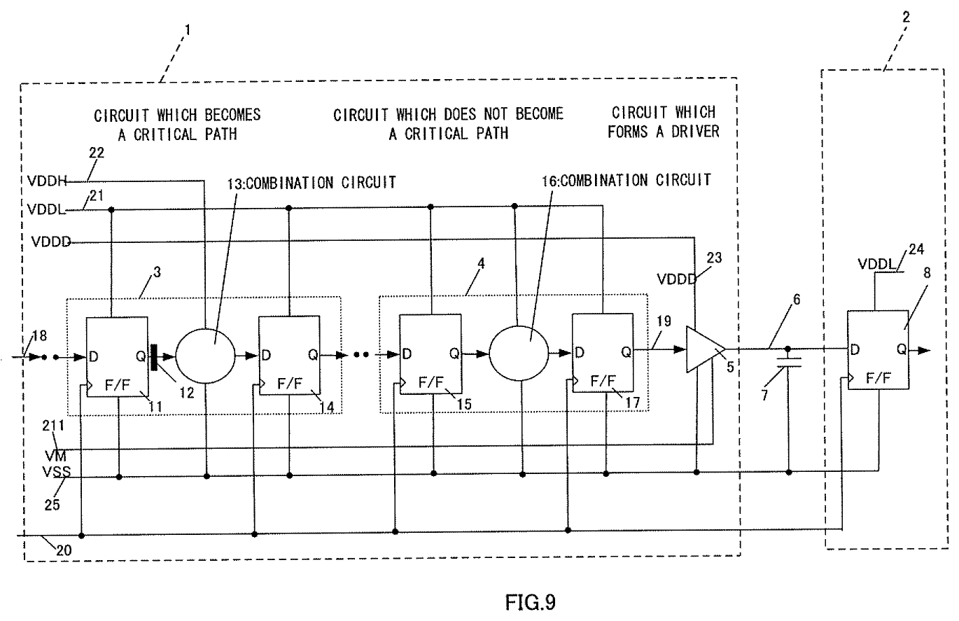

FIG. 9 is a view showing an example of circuit blocks of a semiconductor integrated circuit apparatus according to Embodiment 4 of the present invention, and is a circuit diagram illustrating a mechanism where the semiconductor integrated circuit described in Embodiment 1 is constructed using an SOI process. Components that are same as FIG. 4 are assigned the same reference numerals and explanations of overlapping parts will be omitted.

In FIG. 9, reference numeral 211 is intermediate supply voltage VM and is set to a voltage between a reference supply voltage (VSS) and a supply voltage (VDDD) which is supplied to driver 5.

As for a method of controlling thresholds of the transistors, this embodiment assumes that control is performed through control in a semiconductor process in Embodiments 1 to 3, that is, in general, through control of an amount of channel dope.

However, when the performance required for each functional block of the semiconductor integrated circuit apparatus changes on the time axis, a fixed method such that the threshold of the transistor is determined by control of the amount of channel dope in the manufacturing stage may not meet requirements for low power consumption in the system and high performance.

Thus, in this embodiment, the semiconductor integrated circuit is configured by an SOI process, so that it is possible to control the thresholds of the transistors used for the functional blocks of the semiconductor integrated circuit apparatus and especially control the thresholds of the transistors forming combination circuit 13 in the first circuit block and driver 5 on the time axis.

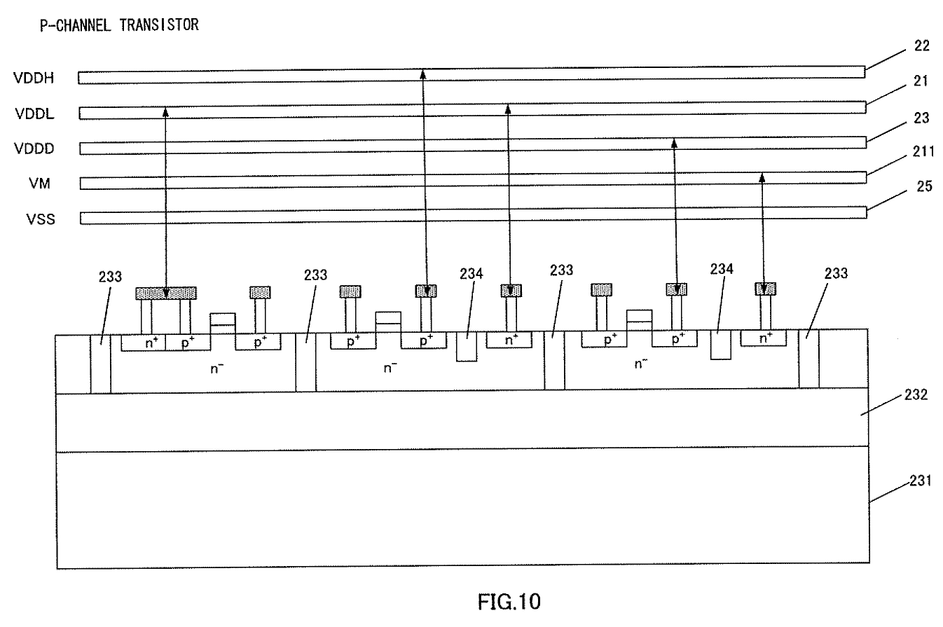

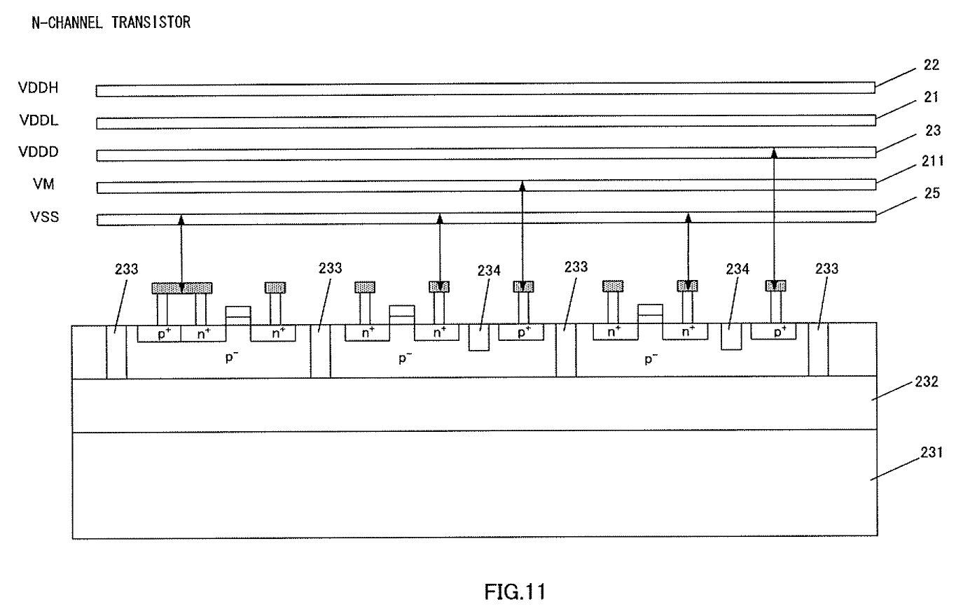

FIG. 10 is a view showing a connection relationship between the P-channel first substrate power line and P-channel semiconductor element in FIG. 9, and FIG. 11 is a view showing a connection relationship between the N-channel first substrate power line and the N-channel semiconductor element in FIG. 9 using a sectional view of a partially depleted type SOI structure, respectively.

Relationships showing how source electrodes and substrate electrodes of P-channel transistors and N-channel transistors of the three types of transistors in FIG. 9, that is, the transistor of combination circuit 13 in the first circuit block which becomes a critical path, the transistor of driver 5 and transistors of other circuits are connected to various supply voltages (VDDH, VDDL, VDDD and VM) and reference voltage (VSS) using a sectional view of a partially depleted type SOI structure.

In FIG. 10 and FIG. 11, reference numeral 231 denotes a silicon support substrate, 232 denotes an embedded oxidation film, 233 denotes a full trench separation and 234 denotes a partial trench separation.

Since the various supply voltages (VDDH, VDDL, VDDD and VM) and reference voltage (VSS) have already been explained in FIG. 2 and FIG. 9, and, therefore, their explanations will be omitted.

By fixing the substrate potential of the P-channel transistors and N-channel transistors, an unstable operation such as a kink phenomenon in the partially depleted type SOI is prevented and also the threshold voltages of the P-channel transistors and the N-channel transistors in the circuit block forming a critical path is controlled using a substrate bias effect.

For example, when the source power supply is connected to the line of supply voltage (VDDH) 22 and the substrate potential of the P-channel transistor is connected to the line of supply voltage (VDDL) 21 like P-channel transistor of combination circuit 13 in first circuit block 3, the absolute value of the threshold voltage of the P-channel transistor is smaller than the threshold voltage of the P-channel transistor when the source power is connected to the line of supply voltage (VDDL) 21 and the substrate potential of the P-channel transistor is also connected to supply voltage (VDDL) 21 like the P-channel transistor in second circuit block 4 forming no critical path. In this way, the source power supply and the substrate potential of P-channel transistor are also connected to the lines of supply voltage (VDDH) 22 and supply voltage (VDDL) 21.

Moreover, as for the P-channel transistor of driver 5, the source power supply of the P-channel transistor is connected to the line of supply voltage (VDDD) 23, and the substrate potential of the P-channel transistor is connected to supply voltage (VM) 211 so as to reduce the threshold voltage. The supply voltage is connected to the line of supply voltage (VDDD) 23.

Furthermore, when the source power supply is connected to the line of reference supply voltage (VSS) 25 and the substrate potential of the N-channel transistor is connected to the line by supply voltage (VM) 211 like the N-channel transistor of combination circuit 13 in first circuit block 3, the threshold voltage of the N-channel transistor is set to be smaller than the threshold voltage of the N-channel transistor of when the source power supply is connected to the line of reference supply voltage (VSS) 25 and the substrate potential of the N-channel transistor is also connected to supply voltage (VSS) 25 like the N-channel transistor in second circuit block 4 forming no critical path.

Moreover, the N-channel transistor as the transistor of driver 5 connects the source power supply of the N-channel transistor to the line of reference supply voltage VSS (25) and connects the substrate potential of the N-channel transistor to supply voltage (VDDD) 23 so as to reduce the threshold voltage.

In other words, it is possible to change the threshold voltages of the P-channel transistor and the N-channel transistor depending on what level of a bias voltage is applied to the P-channel transistor and N-channel transistor respectively. As for the partially depleted type SOI, it is possible to control the source potential and the substrate potential separately for both the P-channel transistor and N-channel transistor. For that reason, if the power line which determines the respective potentials can be wired efficiently, it is possible to reduce the operating current and the leakage current respectively during operation and standby time by taking advantage of the features of the P-channel transistor and the N-channel transistor configured using this partially depleted type SOI.

### Embodiment 5

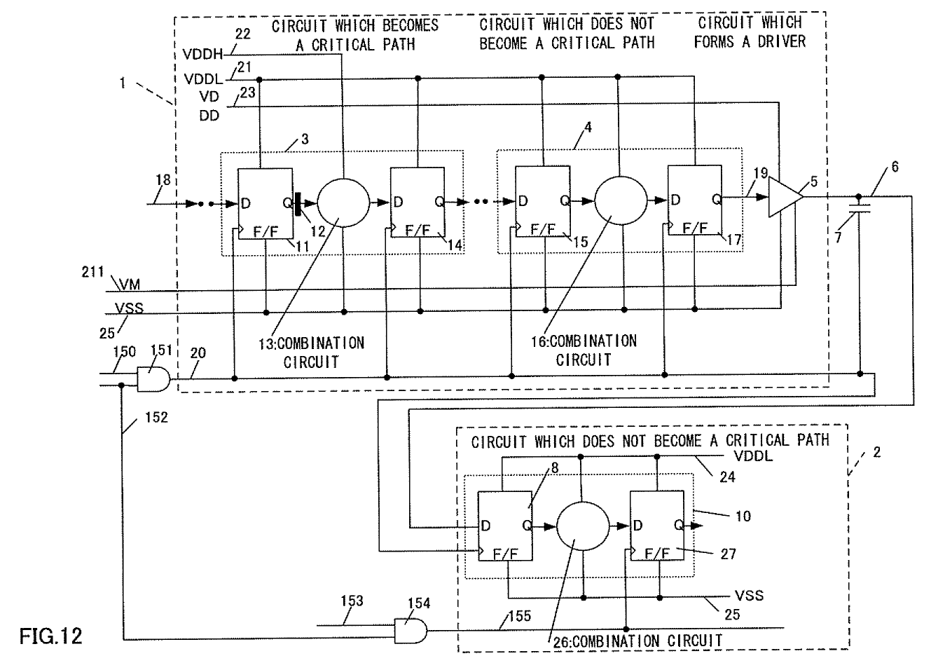

FIG. 12 is a view showing an example of circuit blocks of a semiconductor integrated circuit apparatus according to Embodiment 5 of the present invention and is a circuit diagram illustrating a mechanism where the semiconductor integrated circuit described in Embodiment 2 is formed using an SOI process. Components that are same as FIG. 7 are assigned the same reference numerals and explanations of overlapping parts will be omitted.

Since the circuit operation of FIG. 12 is a combination of the operation of Embodiment 2 in FIG. 7 and the operations of Embodiment 4 in FIG. 10 and FIG. 11, their explanations will be omitted.

### Embodiment 6

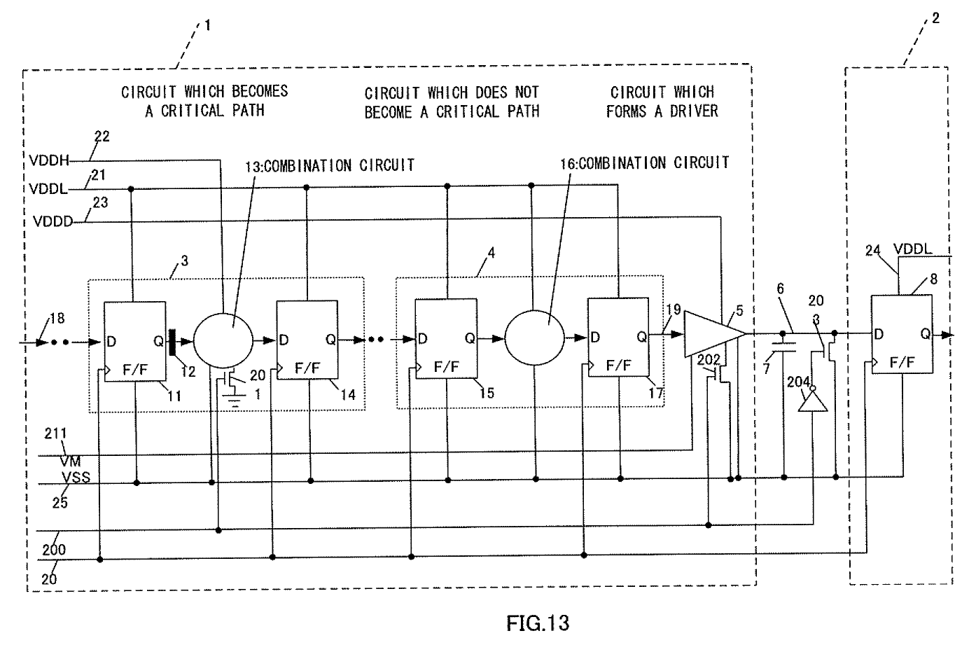

FIG. 13 is a view showing an example of circuit blocks of a semiconductor integrated circuit apparatus according to Embodiment 6 of the present invention and is a circuit diagram illustrating a mechanism where the semiconductor integrated circuit described in Embodiment 3 is formed using an SOI process. Components that are same as FIG. 8 are assigned the same reference numerals and explanations of overlapping parts will be omitted.

Since the circuit operation of FIG. 13 is a combination of the operation of Embodiment 3 in FIG. 8 and the operation of Embodiment 4 in FIG. 10 and FIG. 11, their explanations will be omitted.

### Embodiment 7

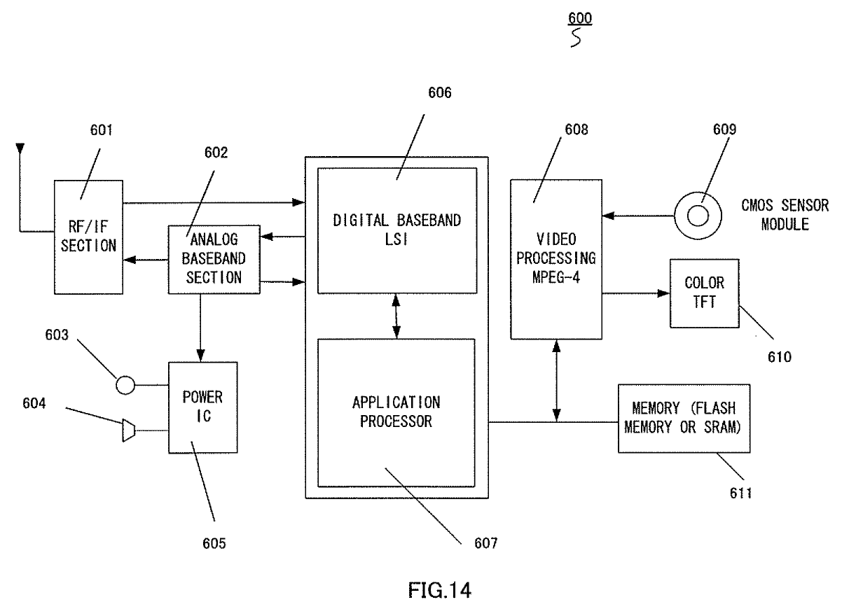

FIG. 14 is a view showing an example of an electronic apparatus mounted with the semiconductor integrated circuit apparatus according to one of Embodiments 1 to 6 of the present invention. The electronic apparatus shown in FIG. 14 is an example of system blocks of a cellular phone with a camera having a video processing function of MPEG.

In FIG. 14, electronic apparatus 600 is provided with: RF/IF (Radio Frequency/Intermediate Frequency) section 601; analog baseband section 602; microphone 603; speaker 604; power IC 605; digital baseband LSI 606; application processor 607; companion LSI for MPEG4 video processing (video processing MPEG-4) 608; CMOS (Complementary MOS) sensor module 609; color TFT 610; and memory 611 formed with flash memory and SRAM (static RAM) or the like.

The degree of integration of an LSI is increasing in recent years, and there is a trend toward integration of digital baseband LSI 606, application processor 607 and MPEG4 video processing companion LSI 608 on a single chip. As an electronic apparatus with the low power consumption type semiconductor integrated circuit apparatus described in both of Embodiments 1 and 2, an LSI for which digital baseband LSI 606, application processor 607, MPEG4 video processing companion LSI 608 are integrated on a single chip and included in the cellular phone with a camera having a video processing function of MPEG as shown in FIG. 14 is appropriate.

The above explanations are exemplifications of preferred embodiments of the present invention and the scope of the present invention is by no means limited to this. For example, the above described embodiments are examples where the present invention is applied to a critical path including wiring delays between functional blocks, but it goes without saying that the present invention is also applicable to a critical path in each functional block.

Furthermore, the embodiments have used terms such as “semiconductor integrated circuit apparatus” and “method of manufacturing the semiconductor integrated circuit apparatus”, but these terms are used for convenience of explanation and it goes without saying that terms such as “semiconductor integrated circuit” may also be used.

Moreover, a type, number and connecting method of the respective circuit sections forming the above described semiconductor integrated circuit apparatus, for example, flip flops are not limited to the above described embodiments.

Moreover, the present invention can be implemented for a semiconductor integrated circuit configured with not only a MOS transistor constructed on a normal silicon substrate but also a MOS transistor having an SOI (Silicon on Insulator) structure.

As described above, according to the present invention, the operation speed is not changed, so that it is possible to further reduce power consumption without forming a critical path. Especially, for example, in a final process of design where a critical path has been eliminated, it is possible to prevent new critical paths from being formed in the circuit block including no critical path and further reduce power consumption.

Furthermore, it is also possible to reduce power consumption of a semiconductor integrated circuit apparatus with a variety of functions in consideration of the problem of critical paths including wiring delays between functional blocks.

Therefore, the semiconductor integrated circuit apparatus according to the present invention is effective for a large-scale semiconductor integrated circuit apparatus (system LSI) which integrates various functions on a single chip.

The present invention is not limited to the above described embodiments, and various variations and modifications may be possible without departing from the scope of the present invention.

This application is based on the Japanese Patent Application No. 2005-300984 filed on Oct. 14, 2005, entire content of which is expressly incorporated by reference herein.

What is claimed is:

1. A semiconductor integrated circuit apparatus comprising a plurality of circuit blocks including no critical path, wherein a threshold voltage of a semiconductor element of a circuit in one circuit block is set to be equal to or lower than a threshold voltage of a semiconductor element of a circuit in another circuit block, and a supply voltage to be supplied to said one circuit block is set to be equal to or lower than a supply voltage to be supplied to said another circuit block, thereby setting power consumption of said one circuit block lower than said another circuit block.

2. A semiconductor integrated circuit apparatus comprising: a first circuit block including a critical path; and second and third circuit blocks including no said critical path, wherein:
a threshold voltage of a semiconductor element of a circuit in said first circuit block is set to be equal to or lower than a threshold voltage of a semiconductor element of a circuit in said second circuit block and a supply voltage to be supplied to said first circuit block is set to be equal to or higher than a supply voltage to be supplied to said second circuit block, thereby eliminating the critical path in said first circuit block; and
a threshold voltage of a semiconductor element of a circuit in said third circuit block is set to be equal to or lower than the threshold voltage of the semiconductor element of the circuit in said second circuit block, and a supply voltage to be supplied to said third circuit block is set to be equal to or lower than the supply voltage to be supplied to said second circuit block, thereby reducing power consumption of said third circuit block.

3. The semiconductor integrated circuit apparatus according to claim 2, wherein the threshold voltage of the semiconductor element of the circuit in said third circuit block is set to equal to or lower than the threshold voltage of said first circuit block.

4. The semiconductor integrated circuit apparatus according to claim 2, wherein the circuit in said third circuit block is a driver that drives a line for transmitting a signal to each block.

5. The semiconductor integrated circuit apparatus according to claim 2, wherein said first circuit block, said second and third circuit blocks constitute a first functional block and the circuit of said third circuit block is a driver that drives a line for transmitting a signal from said first functional block to the circuit in the second functional block.

6. The semiconductor integrated circuit apparatus according to claim 1, wherein each of said plurality of circuit blocks comprises an SOI (Silicon On Insulator) structure comprised of a P-channel element and N-channel element.

7. The semiconductor integrated circuit apparatus according to claim 5, wherein, when power to said first functional block is cut off, a clock signal which sets said first functional block to a standby state is supplied to the circuit in said first functional block and the circuit in said second functional block.

8. The semiconductor integrated circuit apparatus according to claim 5, wherein, when said first functional block is on standby, the supply voltage supplied to the combination circuit in said first circuit block is cut off.

9. The semiconductor integrated circuit apparatus according to claim 5, wherein when said first functional block is on standby, the supply voltage supplied to said driver is cut off.

10. A method of manufacturing a semiconductor integrated circuit apparatus provided with a plurality of circuit blocks including no critical path, the method comprising:
a step of setting a threshold voltage of a semiconductor element of a circuit in one circuit block to be equal to or lower than a threshold voltage of a semiconductor element of a circuit in another circuit block; and
a step of setting a supply voltage to be supplied to said one circuit block to be equal to or lower than a supply voltage to be supplied to said another circuit block.

11. A method of manufacturing a semiconductor integrated circuit apparatus provided with a first circuit block including a critical path, second and third circuit blocks including no said critical path, the method comprising:
a step of setting a threshold voltage of a semiconductor element of a circuit in said first circuit block to be equal to or lower than a threshold voltage of a semiconductor element of a circuit in said second circuit block;
a step of setting a supply voltage to be supplied to said first circuit block to be equal to or higher than a supply voltage to be supplied to said second circuit block;
a step of detecting that the critical path in said first circuit block is eliminated;
a step of setting a threshold voltage of a semiconductor element of a circuit in said third circuit block to be equal to or lower than the threshold voltage of the semiconductor element of the circuit in said second circuit block; and
a step of setting a supply voltage to be supplied to said third circuit block to be equal to or lower than the supply voltage to be supplied to said second circuit block.

12. An electronic apparatus comprising said semiconductor integrated circuit apparatus according to claim 1.

13. An electronic apparatus comprising said method of manufacturing a semiconductor integrated circuit apparatus according to claim 10.
